(19) United States
(12) Patent Application Publication
(10) Pub. No.: US 2009/0085169 A1
(43) Pub. Date: Apr. 2, 2009

(54) METHOD OF ACHIEVING ATOMICALLY SMOOTH SIDEWALLS IN DEEP TRENCHES, AND HIGH ASPECT RATIO SILICON STRUCTURE CONTAINING ATOMICALLY SMOOTH SIDEWALLS

(76) Inventors: Willy Rachmady, Beaverton, OR (US); Brian S. Doyle, Portland, OR (US); Jack Kavalieros, Portland, OR (US); Rajwinder Singh, Fremont, CA (US)

Correspondence Address: INTEL CORPORATION;c/o INTELLEVATE, LLC, P.O. BOX 52050, MINNEAPOLIS, MN, 55402, US

(21) Appl. No.: 11/864,899

(22) Filed: Sep. 28, 2007

(51) Int. Cl. H01L 21/461; H01L 29/06

(52) U.S. Cl. 257/622; 438/706; 257/E29.005; 257/E21.485

(57) ABSTRACT

A high aspect ratio silicon structure comprises a silicon substrate (110) having a surface (111), an electrically insulating layer (120) over portions of the silicon substrate, a hardmask (130) over the electrically insulating layer, and a deep silicon trench (140) formed in the substrate. The deep silicon trench comprises a floor (141) and sidewalls (142) extending away from the floor, and the sidewalls are atomically smooth. In an embodiment, the atomically smooth sidewalls are achieved by providing a substrate having the deep silicon trench formed therein, forming a layer of water over the substrate and within the deep silicon trench, and exposing the substrate to a hydrogen fluoride vapor and to an ozone gas.

### FIELD OF THE INVENTION

The disclosed embodiments of the invention relate generally to deep silicon trench sidewall smoothing, and relate more particularly to ozone-based chemical polish chemistry for producing atomically smooth sidewalls.

### BACKGROUND OF THE INVENTION

High aspect ratio silicon structures are important in a variety of applications, including FinFET transistors, optical waveguide interconnect applications, and deep trench capacitors used in DRAM and elsewhere. The longer etch times required to produce such high aspect ratio structures consume increasingly more mask materials and make it increasingly difficult to control the charges, potentials, and particles used during the etch.

### BRIEF DESCRIPTION OF THE DRAWINGS

The disclosed embodiments will be better understood from a reading of the following detailed description, taken in conjunction with the accompanying figures in the drawings in which:

FIG. 1 is a cross-sectional view of a silicon structure according to an embodiment of the invention;

FIG. 2 is a flowchart illustrating a method of achieving atomically smooth sidewalls in deep trenches according to an embodiment of the invention; and

FIG. 3 is a flowchart illustrating a method of achieving atomically smooth sidewalls in deep trenches according to another embodiment of the invention.

For simplicity and clarity of illustration, the drawing figures illustrate the general manner of construction, and descriptions and details of well-known features and techniques may be omitted to avoid unnecessarily obscuring the discussion of the described embodiments of the invention. Additionally, elements in the drawing figures are not necessarily drawn to scale. For example, the dimensions of some of the elements in the figures may be exaggerated relative to other elements to help improve understanding of embodiments of the present invention. The same reference numerals in different figures denote the same elements.

The terms “first,”, “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments of the invention described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method. Furthermore, the terms “comprise,” “include,” “have,” and any variations thereof, are intended to cover a non-exclusive inclusion, such that a process, method, article, or apparatus that comprises a list of elements is not necessarily limited to those elements, but may include other elements not expressly listed or inherent to such process, method, article, or apparatus.

The terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein. The term “coupled,” as used herein, is defined as directly or indirectly connected in an electrical or non-electrical manner. Objects described herein as being “adjacent to” each other may be in physical contact with each other, in close proximity to each other, or in the same general region or area as each other, as appropriate for the context in which the phrase is used. Occurrences of the phrase “in one embodiment” herein do not necessarily all refer to the same embodiment.

### DETAILED DESCRIPTION OF THE DRAWINGS

In an embodiment of the invention, a high aspect ratio silicon structure comprises a silicon substrate having a surface, an electrically insulating layer over portions of the silicon substrate, a hardmask over the electrically insulating layer, and a deep silicon trench formed in the substrate. The deep silicon trench comprises a floor and sidewalls extending away from the floor, and the sidewalls are atomically smooth. In an embodiment, the atomically smooth sidewalls are achieved by providing a substrate having the deep silicon trench formed therein, forming a layer of water over the substrate and within the deep silicon trench, and exposing the substrate to a hydrogen fluoride vapor and to an ozone gas.

As device scaling continues such that the structure aspect ratio (height/width) goes beyond 10:1, it is increasingly difficult to control sidewall striation and roughening, resulting in lines with elevated line edge roughness. Silicon sidewall roughness, striation, and microtrenching is problematic in a variety of deep trench structures. One method that can be applied to repair sidewall surface roughness is growing sacrificial oxide. This process results in some material loss and substrate thinning. Another known method is hydrogen annealing, but this requires an extremely high temperature and would alter the shape and geometry of the structures and consequently is often not suitable in device fabrication.

Deep trench capacitors with rough sidewalls are harder to fill, and interconnect structures with rough sidewalls suffer from a loss of efficiency. Sidewall smoothing achieved with or disclosed in embodiments of the invention may ensure continuous scaling of trench capacitor aspect ratio (which is a key requirement for DRAM), improve charge carrier mobility on FinFET devices, and reduce scattering losses and other inefficiencies in optical interconnect waveguides.

Embodiments of the invention achieve atomically smooth vertical sidewalls in high aspect ratio silicon structures in deep trench capacitor, FinFET transistor, optical waveguide interconnect, and similar applications by applying a hydrogen fluoride (HF)/ozone (O3) chemistry to chemically polish the sidewall surfaces. In this manner a smooth and clean silicon sidewall surface is obtained without significant loss of the substrate and without change in the structure geometry. This HF/O3 process can also be tuned to produce a silicon surface that is either hydrophobic or hydrophilic depending on the requirement for next layer deposition.

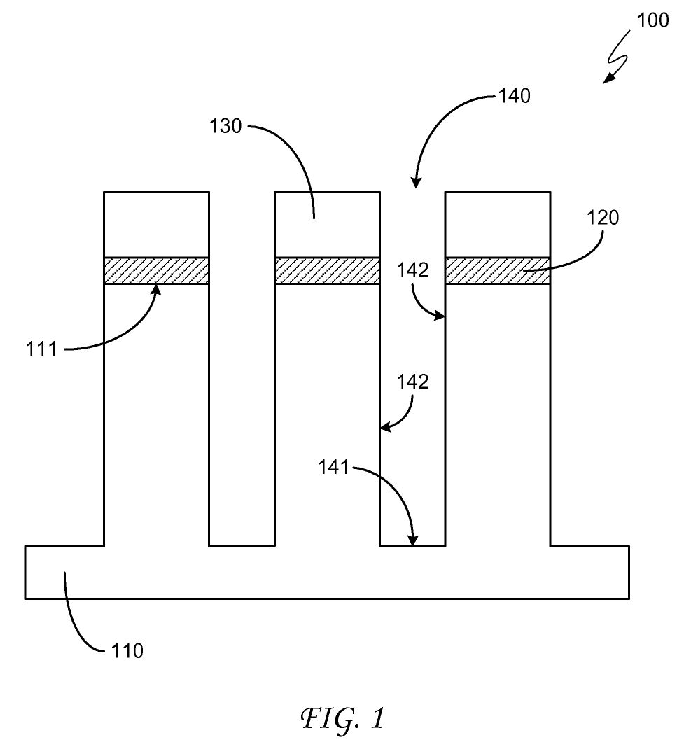

Referring now to the drawings, FIG. 1 is a cross-sectional view of a silicon structure 100, which may be a high aspect ratio silicon structure, according to an embodiment of the invention. As illustrated in FIG. 1, silicon structure 100 comprises a silicon substrate 110 having a surface 111, an electrically insulating layer 120 over portions of silicon substrate 110, a hardmask 130 over electrically insulating layer 120, and a deep silicon trench 140 formed in substrate 110.

Deep silicon trench 140 comprises a floor 141 and sidewalls 142 extending away from floor 141. Sidewalls 142 are atomically smooth, which means, as that phrase is used in this document, that sidewalls 142 vary by no more than 2 nanometers (nm) away from a perfectly straight line. Such atomic smoothness could be confirmed, for example, by performing a roughness measurement using a scanning electron microscope. Subsequent descriptions herein of treatments being performed on surface 111 should be understood as also being performed on floor 141 and sidewalls 142.

In various embodiments, silicon structure 100 could be, or be part of, a deep trench capacitor, a FinFET transistor, an optical interconnect waveguide, or another structure that, like those mentioned, would benefit from an atomically smooth features. In one embodiment, electrically insulating layer 120 comprises silicon dioxide or the like, and in the same or another embodiment, hardmask 130 comprises silicon nitride or the like. In an embodiment, the phrase “high aspect ratio” means an aspect ratio of 10:1 or greater. Similarly, in an embodiment, the phrase “deep trench” means a trench having an aspect ratio of 10:1 or greater.

In one embodiment, surface 111 of silicon substrate 110 is hydrophobic, while in a different embodiment, surface 111 is hydrophilic. A method of causing surface 111 to be hydrophilic or hydrophobic, along with a method of achieving atomically smooth sidewalls, will be described below.

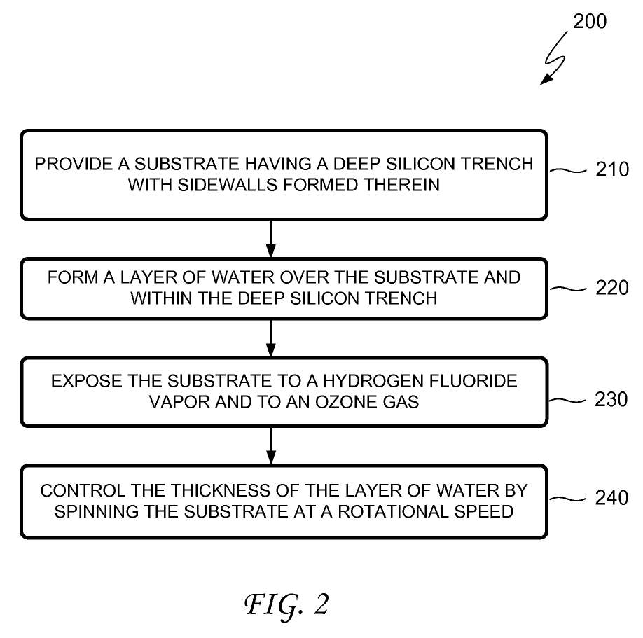

FIG. 2 is a flowchart illustrating a method 200 of achieving atomically smooth sidewalls in deep trenches according to an embodiment of the invention. A step 210 of method 200 is to provide a substrate having a deep silicon trench with sidewalls formed therein. As an example, the substrate can be similar to substrate 110 that is shown in FIG. 1. As another example, the deep silicon trench can be similar to deep silicon trench 140, and the sidewalls can be similar to sidewalls 142. Deep silicon trench 140 with its sidewalls 142 are shown in FIG. 1.

A step 220 of method 200 is to form a layer of water over the substrate and within the deep silicon trench. The layer of water has a thickness, which in one embodiment, is between approximately 2 micrometers (μm) and approximately 10 μm. The thickness of the water layer controls the amount of vapor and gas (discussed in step 230 below) to which the substrate is exposed.

A step 230 of method 200 is to expose the substrate to a hydrogen fluoride vapor and to an ozone gas. In one embodiment, step 230 comprises simultaneously exposing the substrate to the hydrogen fluoride vapor and to the ozone gas. In another embodiment, the substrate can be exposed to the hydrogen fluoride vapor either before or after it is exposed to the ozone gas, but simultaneous exposure is preferred, at least in some embodiments, because it produces the smoothing effects more quickly. In the same or another embodiment, step 230 comprises using an inert gas, such as nitrogen, argon, or the like, as a carrier for the hydrogen fluoride vapor and the ozone gas.

In an embodiment, step 220, step 230, or both, are performed at a temperature less than 100 degrees Celsius. In a particular embodiment, step 220, step 230, or both, are performed at room temperature, which allows the process to be used at any layer in the overall manufacturing process flow.

A step 240 of method 200 is to control the thickness of the layer of water by spinning the substrate at a rotational speed. In one embodiment, the rotational speed is between approximately 200 revolutions per minute (rpm) and approximately 2000 rpm. In one embodiment, step 240 is performed simultaneously with steps 220 and 230.

The overall reaction described in method 200 is contained within the first few monolayers at the surface. As the surface becomes featureless or smooth, there is less surface oxidation occurring, which slows down the overall etching. This characteristic of method 200 may help address critical dimension budget concerns, as it means there will be negligible loss of bulk substrate.

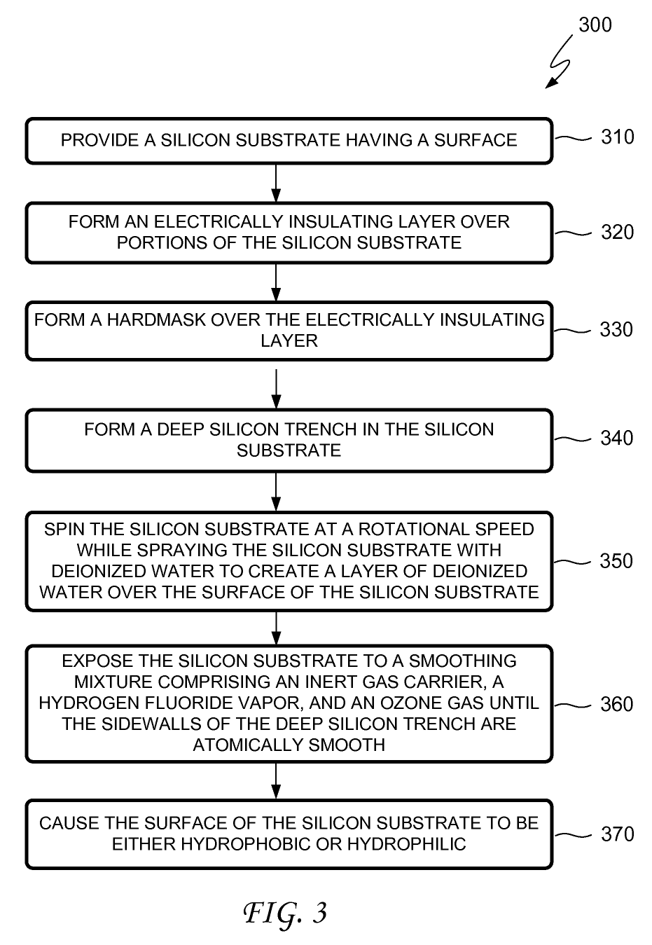

FIG. 3 is a flowchart illustrating a method 300 of achieving atomically smooth sidewalls in deep trenches according to an embodiment of the invention. A step 310 of method 300 is to provide a silicon substrate having a surface. As an example, the silicon substrate can be similar to substrate 110 and the surface of the substrate can be similar to surface 111. Substrate 110 and surface 111 are both shown in FIG. 1.

A step 320 of method 300 is to form an electrically insulating (pad oxide) layer over portions of the silicon substrate. As an example, the electrically insulating layer can be similar to electrically insulating layer 120 that is shown in FIG. 1.

A step 330 of method 300 is to form a hardmask over the electrically insulating layer. As an example, the hardmask can be similar to hardmask 130 that is shown in FIG. 1.

A step 340 of method 300 is to form a deep silicon trench in the silicon substrate. As an example, the deep silicon trench can be similar to deep silicon trench 140 that is shown in FIG. 1. In one embodiment, step 340 comprises performing a dry etch using a mixture of hydrogen bromide (HBr) along with either chlorine (Cl₂) or oxygen (O₂). Due to ion bombardment and non-uniformity on the polymer build-up, step 340 typically results in trench sidewalls having significant striation and surface roughness. The choice between chlorine and oxygen may be made depending on the mask and/or the configuration of the etch chamber. Chlorine is more aggressive, and typically eats away at the mask material.

A step 350 of method 300 is to spin the silicon substrate at a rotational speed while spraying the silicon substrate with deionized water to create a layer of deionized water (DIW) over the surface of the silicon substrate. This rotational speed, according to the physics of centrifugal force, controls the thickness of the DIW boundary layer and the flow of the reactants in this boundary layer, which in turn controls reaction kinetics of the smoothing mixture (discussed in step 360 below) to which the silicon substrate is exposed. More specifically, the rotational speed (the spin rate) acts as a primary variable to control the concentration of the reactants and their residence time at the surface of the wafer. The faster the spin speed, the less time the reactants take to diffuse through the boundary later and also the less time they spend reacting on the wafer.

A step 360 of method 300 is to expose the silicon substrate to a smoothing mixture comprising an inert gas carrier, a hydrogen fluoride vapor, and an ozone gas until the sidewalls of the deep silicon trench are atomically smooth. In at least one embodiment, step 360 begins before step 350 ends. In other words, the silicon substrate is exposed to the smoothing mixture while the silicon substrate is still being spun and while it is still being sprayed with deionized water. The cycle of oxidization (by O₃) and dissolution (by HF) occurring within the thin DIW layer provides a polishing effect on the rough silicon, thereby producing a much smoother surface. In an embodiment, the O₃ and HF flows are alternated, so repetitive cycles of oxidation by O₃ and dissolution by HF smooth out features (steps, kinks, or divots) on the substrate surface.

In one embodiment, step 360 is performed at a temperature less than 100 degrees Celsius, and in a particular embodiment step 360 is performed at room temperature. In the same or another embodiment, the inert gas carrier comprises nitrogen. In another embodiment the inert gas carrier is argon.

In one embodiment, step 360 further comprises providing the smoothing mixture such that the hydrogen fluoride vapor represents approximately 2 percent of the smoothing mixture and the ozone gas represents approximately 0.2 percent of the smoothing mixture.

A step 370 of method 300 is to cause the surface of the silicon substrate to be either hydrophobic or hydrophilic. In one embodiment, if the surface of the silicon substrate is to be hydrophobic, as when, for example, an epitaxial layer with hydrogen-terminated silicon is desired, step 370 comprises changing the smoothing mixture by removing the ozone gas after a first time period such that the smoothing mixture subsequently comprises only the hydrogen fluoride vapor. The surface of the silicon substrate is then exposed to the new smoothing mixture (the one without the ozone gas) for a second time period. It should be understood that the first time period mentioned in this paragraph is the time period during which the surface of the silicon substrate is exposed to the original smoothing mixture-the mixture containing both hydrogen fluoride vapor and ozone gas-during step 360. As an example, the first time period can range between approximately one minute and approximately ten minutes and the second time period can range between approximately five seconds and approximately 30 seconds.

In another embodiment, if the surface of the silicon substrate is to be hydrophilic, as when, for example, an atomic layer deposition (ALD) metal needs to react with a hydroxyl group, step 370 comprises changing the smoothing mixture by removing the hydrogen fluoride vapor after a first time period such that the smoothing mixture subsequently comprises only the ozone gas. The surface of the silicon substrate is then exposed to the new smoothing mixture (the one without the hydrogen fluoride vapor) for a second time period. It should be understood that the first time period mentioned in this paragraph is the time period during which the surface of the silicon substrate is exposed to the original smoothing mixture—the mixture containing both hydrogen fluoride vapor and ozone gas—during step 360. As an example, the first time period can range between approximately one minute and approximately ten minutes and the second time period can range between approximately five seconds and approximately 30 seconds. In at least one embodiment, the silicon substrate is sprayed with DIW, as set forth in step 350, during the entire time during which the silicon substrate is exposed to the smoothing mixture, whatever the composition of that smoothing mixture may be.

The overall reaction described in method 300 is contained within the first few monolayers at the surface. As the surface becomes featureless or smooth, there is less surface oxidation occurring, which slows down the overall etching. This characteristic of method 300 may help address critical dimension budget concerns, as it means there will be negligible loss of bulk substrate.

Although the invention has been described with reference to specific embodiments, it will be understood by those skilled in the art that various changes may be made without departing from the spirit or scope of the invention. Accordingly, the disclosure of embodiments of the invention is intended to be illustrative of the scope of the invention and is not intended to be limiting. It is intended that the scope of the invention shall be limited only to the extent required by the appended claims. For example, to one of ordinary skill in the art, it will be readily apparent that the silicon structure and related methods discussed herein may be implemented in a variety of embodiments, and that the foregoing discussion of certain of these embodiments does not necessarily represent a complete description of all possible embodiments.

Additionally, benefits, other advantages, and solutions to problems have been described with regard to specific embodiments. The benefits, advantages, solutions to problems, and any element or elements that may cause any benefit, advantage, or solution to occur or become more pronounced, however, are not to be construed as critical, required, or essential features or elements of any or all of the claims.

Moreover, embodiments and limitations disclosed herein are not dedicated to the public under the doctrine of dedication if the embodiments and/or limitations: (1) are not expressly claimed in the claims; and (2) are or are potentially equivalents of express elements and/or limitations in the claims under the doctrine of equivalents.

What is claimed is:

1. A method of achieving atomically smooth sidewalls in deep trenches, the method comprising:
providing a substrate having a deep silicon trench formed therein, the deep silicon trench having sidewalls;
forming a layer of water over the substrate and within the deep silicon trench, where the layer of water has a thickness; and
exposing the substrate to a hydrogen fluoride vapor and to an ozone gas.

2. The method of claim 1 further comprising:
controlling the thickness of the layer of water by spinning the substrate at a rotational speed.

3. The method of claim 2 wherein:
the thickness of the layer of water is between approximately 2 micrometers and approximately 10 micrometers.

4. The method of claim 2 wherein:
the substrate is simultaneously exposed to the hydrogen fluoride vapor and to the ozone gas.

5. The method of claim 2 wherein:
exposing the substrate to the hydrogen fluoride vapor and to the ozone gas comprises using an inert gas as a carrier for the hydrogen fluoride vapor and the ozone gas.

6. The method of claim 5 wherein:
forming the layer of water and exposing the substrate to the hydrogen fluoride vapor and to the ozone gas is done at a temperature less than 100 degrees Celsius.

7. The method of claim 6 wherein:
forming the layer of water and exposing the substrate to the hydrogen fluoride vapor and to the ozone gas is done at room temperature.

8. A method of achieving atomically smooth sidewalls in deep trenches, the method comprising:
providing a silicon substrate having a surface;
forming an electrically insulating layer over portions of the silicon substrate;
forming a hardmask over the electrically insulating layer;
forming a deep silicon trench in the silicon substrate;
spinning the silicon substrate at a rotational speed while spraying the silicon substrate with deionized water to create a layer of deionized water over the surface of the silicon substrate; and
exposing the silicon substrate to a smoothing mixture comprising an inert gas carrier, a hydrogen fluoride vapor, and an ozone gas until a sidewall of the deep silicon trench is atomically smooth.

9. The method of claim 8 wherein:
exposing the silicon substrate to a smoothing mixture is done at a temperature less than 100 degrees Celsius.

10. The method of claim 9 wherein:
exposing the silicon substrate to a smoothing mixture is done a room temperature.

11. The method of claim 8 wherein:
forming the deep silicon trench comprises performing a dry etch using a mixture of hydrogen bromide and either chlorine or oxygen.

12. The method of claim 8 wherein:
the rotational speed is between approximately 200 revolutions per minute and approximately 2000 revolutions per minute.

13. The method of claim 8 wherein:
the hydrogen fluoride vapor represents approximately 2 percent of the smoothing mixture; and
the ozone gas represents approximately 0.2 percent of the smoothing mixture.

14. The method of claim 13 wherein:
the inert gas carrier comprises nitrogen.

15. The method of claim 8 further comprising:
causing the surface of the silicon substrate to be hydrophobic.

16. The method of claim 15 wherein:
causing the surface of the silicon substrate to be hydrophobic comprises changing the smoothing mixture by removing the ozone gas after a first time period.

17. The method of claim 8 further comprising:
causing the surface of the silicon substrate to be hydrophilic.

18. The method of claim 17 wherein:
causing the surface of the silicon substrate to be hydrophilic comprises changing the smoothing mixture by removing the hydrogen fluoride vapor after a first time period.

19. A high aspect ratio silicon structure comprising:
a silicon substrate having a surface;
an electrically insulating layer over portions of the silicon substrate;
a hardmask over the electrically insulating layer; and
a deep silicon trench formed in the silicon substrate,
wherein:
the deep silicon trench comprises a floor and sidewalls extending away from the floor; and
the sidewalls are atomically smooth.

20. The high aspect ratio silicon structure of claim 19 wherein:
the surface of the silicon substrate is hydrophobic.

21. The high aspect ratio silicon structure of claim 19 wherein:
the surface of the silicon substrate is hydrophilic.

22. The high aspect ratio silicon structure of claim 19 wherein:
the electrically insulating layer comprises silicon dioxide.

23. The high aspect ratio silicon structure of claim 19 wherein:
the hardmask comprises silicon nitride.

24. The high aspect ratio silicon structure of claim 19 wherein:
the high aspect ratio silicon structure is a deep trench capacitor.

25. The high aspect ratio silicon structure of claim 19 wherein:
the high aspect ratio silicon structure is a FinFET transistor.

26. The high aspect ratio silicon structure of claim 19 wherein:
the high aspect ratio silicon structure is an optical interconnect waveguide.

27. A high aspect ratio silicon structure comprising:
a silicon substrate having a surface;
a silicon dioxide layer over portions of the silicon substrate;
a silicon nitride mask over the silicon dioxide layer; and
a deep silicon trench having an aspect ratio of at least 10:1 formed in the silicon substrate,
wherein:
the deep silicon trench comprises a floor and sidewalls extending away from the floor; and
the sidewalls are atomically smooth.

28. The high aspect ratio silicon structure of claim 27 wherein:
the surface of the silicon substrate is hydrophobic.

29. The high aspect ratio silicon structure of claim 27 wherein:
the surface of the silicon substrate is hydrophilic.
